(19) United States
(12) Patent Application Publication
(10) Pub. No.: US 2025/0203871 A1
(43) Pub. Date: Jun. 19, 2025

(54) SEMICONDUCTOR DEVICE

(71) Applicant: SAMSUNG ELECTRONICS CO., LTD., Suwon-si (KR)

(72) Inventors: Byongju Kim, Suwon-si (KR); Youjung Kim, Suwon-si (KR)

(21) Appl. No.: 18/781,730

(22) Filed: Jul. 23, 2024

(30) Foreign Application Priority Data
Dec. 19, 2023 (KR) 10-2023-0186087

(51) Int. Cl. H10B 43/40; H10B 41/27; H10B 41/41; H10B 43/27

(52) U.S. Cl. CPC H10B 43/40; H10B 41/27; H10B 41/41; H10B 43/27

(57) ABSTRACT

A semiconductor device may include a substrate, a doped region on the substrate, a gate structure on the substrate, an insulating layer covering the gate structure and the doped region, a first contact extending through the insulating layer and connected to the gate structure, and a first film formation inhibition pattern disposed between the gate structure and the first contact. The first film formation inhibition pattern includes a halogen element.

### CROSS-REFERENCE TO RELATED APPLICATIONS

This U.S. non-provisional patent application claims priority under 35 U.S.C. § 119 to Korean Patent Application No. 10-2023-0186087, filed on Dec. 19, 2023, in the Korean Intellectual Property Office, the entire contents of which are hereby incorporated by reference.

### BACKGROUND

Due to their small-sized, multifunctional, and/or low-cost characteristics, semiconductor devices are being esteemed as important elements in the electronics industry. The semiconductor devices are classified into a semiconductor memory device for storing data, a semiconductor logic device for processing data, and a hybrid semiconductor device including both of memory and logic elements.

With the recent trend of high speed and low power consumption of electronic devices, semiconductor devices in the electronic devices are also required to have high operating speeds and/or low operating voltages, and in order to satisfy this requirement, it is necessary to increase an integration density of the semiconductor device. However, as the integration density of the semiconductor device increases, the semiconductor device may suffer from deterioration in electrical characteristics and production yield. Accordingly, many studies are being conducted to improve the electrical characteristics and production yield of the semiconductor device.

### SUMMARY

A semiconductor device is described with improved electrical and reliability characteristics.

A semiconductor device may include a substrate, a doped region on the substrate, a gate structure on the substrate, an insulating layer covering the gate structure and the doped region, a first contact provided to extend through the insulating layer and connected to the gate structure, and a first film formation inhibition pattern disposed between the gate structure and the first contact. The first film formation inhibition pattern may contain a halogen element.

A semiconductor device may include a substrate, a doped region on the substrate, a gate structure on the substrate, the gate structure including a gate metal pattern, an insulating layer covering the gate structure and the doped region, a first contact provided to extend through the insulating layer and connected to the gate metal pattern, and a first film formation inhibition pattern disposed between the gate metal pattern and the first contact. The first film formation inhibition pattern may be in contact with a top surface of the gate metal pattern.

A semiconductor device may include a substrate, an isolation region on the substrate, a device isolation layer on the isolation region, a doped region on the substrate, a gate structure on the substrate, the gate structure including a gate metal pattern, an insulating layer covering the doped region and the gate structure, a gate contact provided to extend through the insulating layer and connected to the gate metal pattern, a source/drain pattern provided to extend through the insulating layer and connected to the doped region, a source/drain contact provided to extend through the insulating layer, connected to the source/drain pattern, and disposed on the source/drain pattern, a first film formation inhibition pattern disposed between the insulating layer and the gate contact, and a second film formation inhibition pattern disposed between the insulating layer and the source/drain pattern. A level of a top surface of the source/drain pattern may be higher than a level of a top surface of the gate metal pattern, and the first and second film formation inhibition patterns may contain a halogen element.

### BRIEF DESCRIPTION OF THE DRAWINGS

FIG. 1 is a plan view illustrating an example semiconductor device.

FIG. 2 is a plan view illustrating an example semiconductor device.

FIG. 3 is a sectional view taken along a line A1-A1′ of FIG. 1.

FIG. 4A is an enlarged sectional view illustrating a portion ‘CU1’ of FIG. 3.

FIG. 4B is an enlarged sectional view illustrating a portion ‘CU2’ of FIG. 3.

FIG. 5 is a sectional view illustrating an example semiconductor device.

FIGS. 5, 6, 7, 8, 10, 11, 12, 13, and 14 are sectional views illustrating a method of fabricating the semiconductor device of FIG. 3.

FIG. 9A is an enlarged sectional view illustrating a portion ‘CU3’ of FIG. 8.

FIG. 9B is an enlarged sectional view illustrating a portion ‘CU4’ of FIG. 8.

FIG. 15 is a schematic diagram illustrating an electronic system including an example semiconductor device.

FIG. 16 is a perspective view schematically illustrating an electronic system including an example semiconductor device.

FIGS. 17 and 18 are sectional views schematically illustrating a semiconductor package.

FIG. 19 is a plan view illustrating an example semiconductor device.

FIG. 20 is a sectional view taken along a line A2-A2′ of FIG. 19.

### DETAILED DESCRIPTION

Example implementations will now be described more fully with reference to the accompanying drawings, in which example implementations are shown. Like reference numerals in the drawings denote like elements, and thus their description will be omitted.

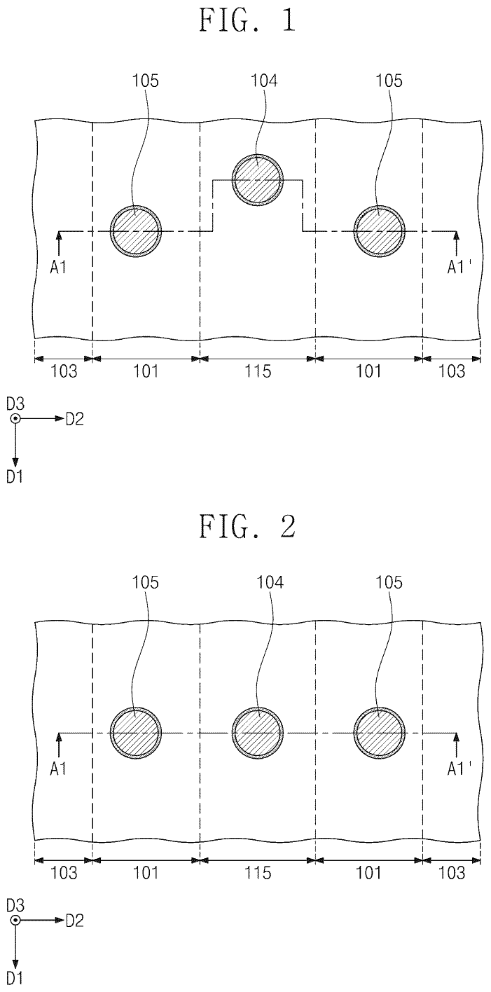

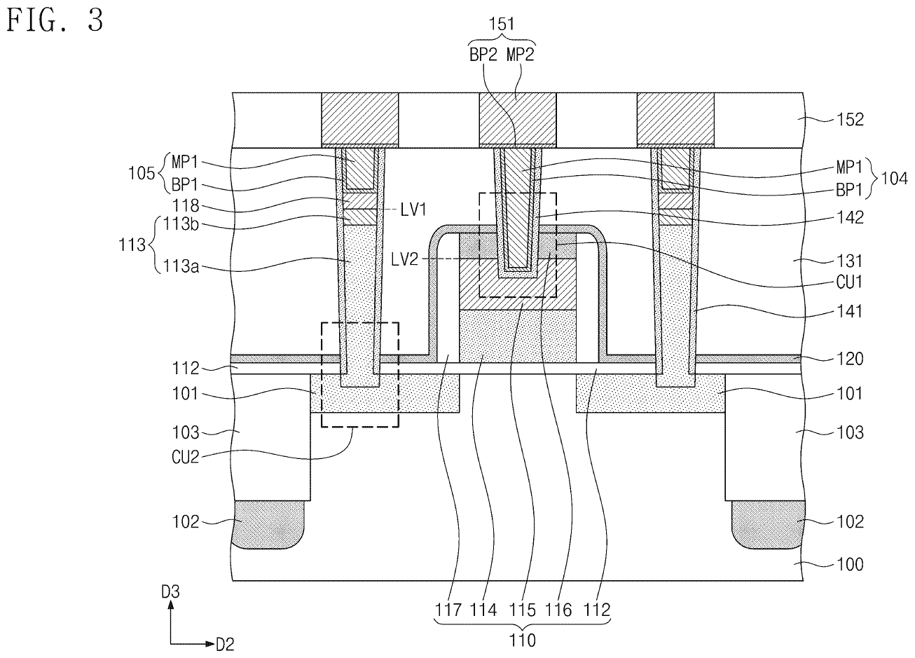

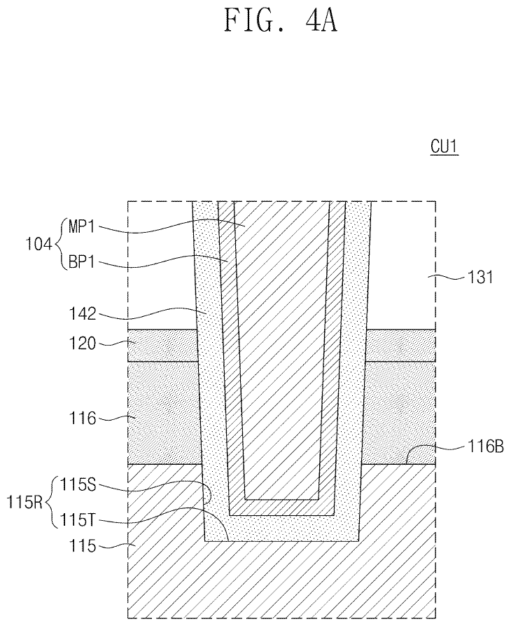

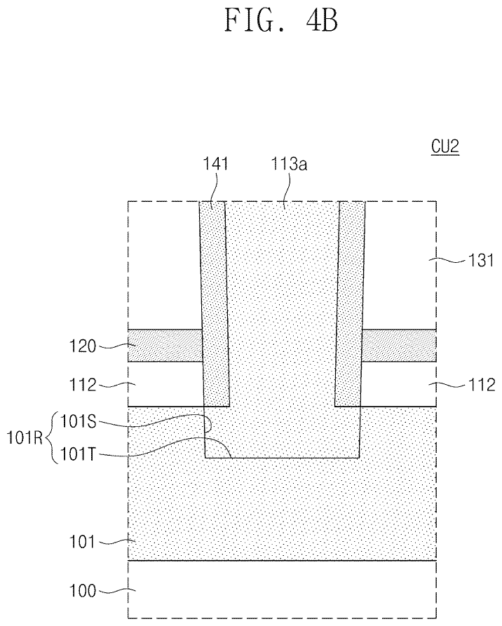

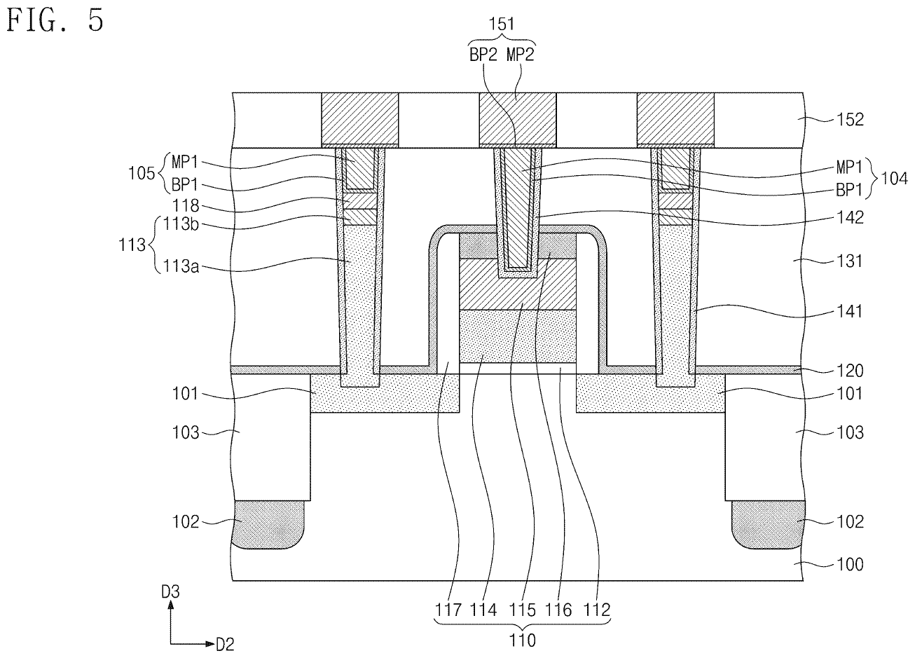

FIG. 1 is a plan view illustrating an example semiconductor device. FIG. 2 is a plan view illustrating an example semiconductor device. FIG. 3 is a sectional view taken along a line A1-A1′ of FIG. 1. FIG. 4A is an enlarged sectional view illustrating a portion ‘CU1’ of FIG. 3. FIG. 4B is an enlarged sectional view illustrating a portion ‘CU2’ of FIG. 3. FIG. 5 is a sectional view illustrating a semiconductor device.

Referring to FIGS. 1 and 3, a semiconductor device may include a substrate 100. The substrate 100 may be a plate-shaped structure that is extended parallel to a plane defined by a first direction D1 and a second direction D2. The first and second directions D1 and D2 may not be parallel to each other. In some implementations, the first and second directions D1 and D2 may be two different horizontal directions, which are orthogonal to each other. In some implementations, the substrate 100 may be a semiconductor substrate. As an example, the substrate 100 may be formed of or include silicon, germanium, silicon-germanium, GaP, or GaAs. In some implementations, the substrate 100 may be a silicon-on-insulator (SOI) substrate or a germanium-on-insulator (GOI) substrate.

Isolation regions 102 may be provided on the substrate 100. The isolation region 102 may be formed by doping the substrate 100 with impurities. The isolation region 102 may contain impurities of a first conductivity type. In some implementations, the first conductivity type may be p-type, and the isolation region 102 may contain boron atoms.

Device isolation layers 103 may be provided on the substrate 100. The device isolation layer 103 may be provided on the isolation region 102. The device isolation layer 103 may be overlapped with the isolation region 102 in a third direction D3. The third direction D3 may not be parallel to the first and second directions D1 and D2. As an example, the third direction D3 may be a vertical direction orthogonal to the first and second directions D1 and D2. The device isolation layer 103 may be formed of or include an insulating material.

A transistor may be provided on the substrate 100. The transistor may be provided between the device isolation layers 103. The transistor may be provided between the isolation regions 102. The transistor may include doped regions 101, source/drain patterns 113, and a gate structure 110.

The doped region 101 may be formed by doping the substrate 100 with impurities. The doped region 101 may contain impurities of a second conductivity type. In some implementations, the second conductivity type may be n-type, and the doped region 101 may contain phosphorus (P). In some implementations, the first conductivity type may be n-type, and the second conductivity type may be p-type. The doped region 101 may have a lightly-doped drain (LDD) structure. A portion of the substrate 100 adjacent to the doped region 101 may contain impurities of the first conductivity type.

The source/drain pattern 113 may be provided on the doped region 101. The source/drain pattern 113 may be connected to the doped region 101. The source/drain pattern 113 may include a first portion 113a on the doped region 101 and a second portion 113b on the first portion 113a. A first portion 113a and the second portion 113b of the source/drain pattern 113 may be formed of or include poly silicon. The first portion 113a and a second portion 113b of the source/drain pattern 113 may contain impurities of the second conductivity type. A concentration of the second conductivity type impurities in the doped region 101 may be a first concentration. A concentration of the second conductivity type impurities in the second portion 113b of the source/drain pattern 113 may be a second concentration. The first concentration of the doped region 101 may be lower than the second concentration of the second portion 113b of the source/drain pattern 113. A concentration of the second conductivity type impurities in the first portion 113a of the source/drain pattern 113 may be a third concentration. The third concentration of the first portion 113a of the source/drain pattern 113 may be lower than the second concentration of the second portion 113b of the source/drain pattern 113. In some implementations, the first portion 113a of the source/drain pattern 113 may not contain an impurity. For example, the first portion 113a of the source/drain pattern 113 may be formed of or include undoped poly silicon. A bottom surface of the first portion 113a of the source/drain pattern 113 may be in contact with a top surface of the doped region 101. The second portion 113b the second portion is spaced apart from the doped region 101. A junction pattern 118 may be disposed on the second portion 113b of the source/drain pattern 113. The junction pattern 118 may be disposed between a second contact 105, which will be described below, and the second portion 113b. The junction pattern 118 may include at least one of metal-silicon compounds (e.g., silicide) and may be formed of or include, for example, CoSiₓ.

The gate structure 110 may be disposed between the source/drain patterns 113. The gate structure 110 may include a gate insulating layer 112, a first gate conductive pattern 114, a second gate conductive pattern 115, and a gate capping pattern 116, and gate spacers 117. The gate insulating layer 112 may be disposed on the substrate 100 and may be extended to cover a top surface of the doped region 101 and a top surface of the device isolation layer 103. A portion of the gate insulating layer 112, which is overlapped with the first gate conductive pattern 114 in the third direction D3, may be used to electrically separate a channel region of a transistor from a gate electrode (e.g., 114) and to control a voltage difference between the channel region and the gate electrode or to control a threshold voltage of the transistor. In some implementations, as shown in FIG. 5, the gate insulating layer 112 may be locally provided in a region, which is placed between the spacers 117 and is overlapped with the first gate conductive pattern 114 in the third direction D3. The gate insulating layer 112 may include an insulating material. For example, the gate insulating layer 112 may be formed of or include at least one of oxide materials. The first gate conductive pattern 114 may be disposed on the gate insulating layer 112. The first gate conductive pattern 114 may include a conductive material. For example, the first gate conductive pattern 114 may be formed of or include poly silicon. The second gate conductive pattern 115 may be disposed on the first gate conductive pattern 114. The second gate conductive pattern 115 may include a metal material. In the present specification, the second gate conductive pattern 115 may be referred to as a gate metal pattern 115. The second gate conductive pattern 115 may be formed of or include tungsten (W). The gate capping pattern 116 may be disposed on the second gate conductive pattern 115. The gate capping pattern 116 may include an insulating material (e.g., silicon nitride (SiN)). The gate spacers 117 may be formed to cover a top surface of the gate insulating layer 112, side surfaces of the first gate conductive pattern 114, side surfaces of the second gate conductive pattern 115, and side surfaces of the gate capping pattern 116. The gate spacer 117 may include an insulating material (e.g., an oxide material). A level LV1 of a top surface of the second portion 113b of the source/drain pattern 113 may be higher than a level LV2 of a top surface of the second gate conductive pattern 115.

Insulating layers 120, 131, and 152 may be provided to cover the device isolation layers 103, the doped regions 101, and the gate structure 110. The insulating layers 120, 131, and 152 may include a protection layer 120, a first insulating layer 131, and a second insulating layer 152. The protection layer 120 may be in contact with the gate insulating layer 112, the gate spacers 117, and the gate capping pattern 116. The protection layer 120 may include an insulating material (e.g., silicon nitride). The first insulating layer 131 may be disposed on the protection layer 120. The first insulating layer 131 may be formed on a region where the gate structure 110 is not formed and may have a thickness that is larger than that of the gate structure 110. For example, the first insulating layer 131 may be formed of or include silicon oxide (SiO₂). The second insulating layer 152 may be disposed on the first insulating layer 131. For example, the second insulating layer 152 may be formed of or include silicon oxide (SiO₂). There may be no observable interface between the first insulating layer 131 and the second insulating layer 152.

As shown in FIGS. 1 and 2, a first contact 104 may be provided on the second gate conductive pattern 115, and the second contact 105 may be provided on the doped region 101. In the present specification, the first contact 104 may be referred to as a gate contact 104. In the present specification, the second contact 105 may be referred to as a source/drain contact 105.

The first contact 104 may be connected to the second gate conductive pattern 115, and the second contact 105 may be connected to the doped region 101 through the junction pattern 118 and the source/drain pattern 113. The first and second contacts 104 and 105 may have a circular shape or a circle-like shape, when viewed in a plan view. For example, as shown in FIG. 1, the first contact 104 may be spaced apart from the second contact 105, the junction pattern 118, and the source/drain pattern 113 in the first and second directions D1 and D2. In other words, the first contact 104 may be spaced apart from the second contact 105, the junction pattern 118, the source/drain pattern 113 in a diagonal direction. As shown in FIG. 2, the first contact 104 may be spaced apart from the second contact 105, the junction pattern 118, and the source/drain pattern 113 in the first direction D1 only.

Each of the first and second contacts 104 and 105 may be formed of or include at least one of metallic materials. Each of the first and second contacts 104 and 105 may include a first barrier pattern BP1 and a first conductive pattern MP1 on the first barrier pattern BP1. The first barrier pattern BP1 may be formed of or include at least one of titanium (Ti), titanium nitride (TiN), tantalum (Ta), or tantalum nitride (TaN). The first conductive pattern MP1 may be formed of or include at least one of copper (Cu), aluminum (A1), silver (Ag), tungsten (W), palladium (Pd), or tungsten (W). In some implementations, the first conductive pattern MP1 may be formed of or include tungsten (W).

Referring to FIGS. 3 and 4A, the first contact 104 may be formed to extend through the first insulating layer 131, the protection layer 120, and the gate capping pattern 116 and may be extended into an upper portion of the second gate conductive pattern 115. The first contact 104 may be extended to a level that is lower than a level of a bottom surface 116B of the gate capping pattern 116 (or the uppermost surface of the second gate conductive pattern 115).

A first recess 115R may be formed in an upper portion of the second gate conductive pattern 115, and the first contact 104 may be provided to fill the first recess 115R.

A first film formation inhibition pattern 142 may be disposed between the first contact 104 and the first insulating layer 131, between the first contact 104 and the protection layer 120, and between the first contact 104 and the gate capping pattern 116, and side and bottom surfaces 115S and 115T of the first recess 115R of the second gate conductive pattern 115. The first film formation inhibition pattern 142 may be in direct contact not only with the first insulating layer 131, the protection layer 120, and the gate capping pattern 116, but also with the side and bottom surfaces 115S and 115T of the first recess 115R of the second gate conductive pattern 115. The first film formation inhibition pattern 142 may be in direct contact with the first barrier pattern BP1 of the first contact 104. In some implementations, the first barrier pattern BP1 of the first contact 104 may be omitted, and the first film formation inhibition pattern 142 may be in direct contact with the first conductive pattern MP1 of the first contact 104.

The first film formation inhibition pattern 142 may include a halogen element. The halogen element may include one of fluorine (F), chlorine (Cl), bromine (Br), or iodine (I). As an example, a portion of the first film formation inhibition pattern 142, which is in contact with the first insulating layer 131, may include at least one of SiOF, SiOCl, or SiOBr, which is formed by replacing at least one of elements in silicon oxide with a halogen element. As another example, there may be a measurable halogen element at an interface between the first film formation inhibition pattern 142 and the protection layer 120 and at an interface between the first film formation inhibition pattern 142 and the gate capping pattern 116.

Referring to FIGS. 3 and 4B, the source/drain pattern 113 may be provided to extend through a portion of the first insulating layer 131, the protection layer 120, the gate insulating layer 112, and an upper portion of the doped region 101. A second recess 101R may be formed in an upper portion of the doped region 101, and the source/drain pattern 113 may be formed to fill the second recess 101R. The junction pattern 118 and the second contact 105 may extend through a remaining portion of the first insulating layer 131.

A second film formation inhibition pattern 141 may be disposed between the source/drain pattern 113 and the first insulating layer 131, between the source/drain pattern 113 and the protection layer 120, and between the source/drain pattern 113 and the gate insulating layer 112. The second film formation inhibition pattern 141 may be in contact with the first insulating layer 131, the protection layer 120, and the gate insulating layer 112. The second film formation inhibition pattern 141 may not be interposed between the source/drain pattern 113 and the second recess 101R of the doped region 101. The second film formation inhibition pattern 141 may not be in contact with the doped region 101. The second film formation inhibition pattern 141 may be extended into spaces between the junction pattern 118 and the first insulating layer 131 and between the second contact 105 and the first insulating layer 131. The second film formation inhibition pattern 141 may be in direct contact with a side surface of the junction pattern 118 and a side surface of the second contact 105. The second film formation inhibition pattern 141 may be in direct contact with the first barrier pattern BP1 of the second contact 105. In some implementations, the first barrier pattern BP1 of the second contact 105 may be omitted, and the second film formation inhibition pattern 141 may be in direct contact with the first conductive pattern MP1 of the second contact 105.

The second film formation inhibition pattern 141 may contain a halogen element, similar to the first film formation inhibition pattern 142. As an example, a portion of the second film formation inhibition pattern 141, which is in contact with the first insulating layer 131, may include at least one of SiOF, SiOCl, or SiOBr, which is formed by replacing at least one of the elements in silicon oxide with a halogen element. As another example, an interface between the second film formation inhibition pattern 141 and the protection layer 120 may contain a halogen element, and the halogen element may be observed at the interface.

The second insulating layer 152 and conductive lines 151 may be disposed on the first contact 104, the second contact 105, and the first insulating layer 131. The second insulating layer 152 may be formed of or include silicon oxide. In some implementations, the first insulating layer 131 and the second insulating layer 152 may be observed as a single insulating layer, without an observable boundary therebetween. The conductive lines 151 may include a second barrier pattern BP2 and a second conductive pattern MP2. The second barrier pattern BP2 and the second conductive pattern MP2 may include different metallic materials, respectively. The conductive lines 151 may be connected to the first contact 104 and the second contacts 105, respectively.

The semiconductor device may include the source/drain pattern 113, which is extended in the third direction D3. As a result, a current path between the second contact 105 and the gate structure 110 may be relatively long. Thus, a size of the doped region 101 may be relatively small, and an integration density of the semiconductor device may be increased.

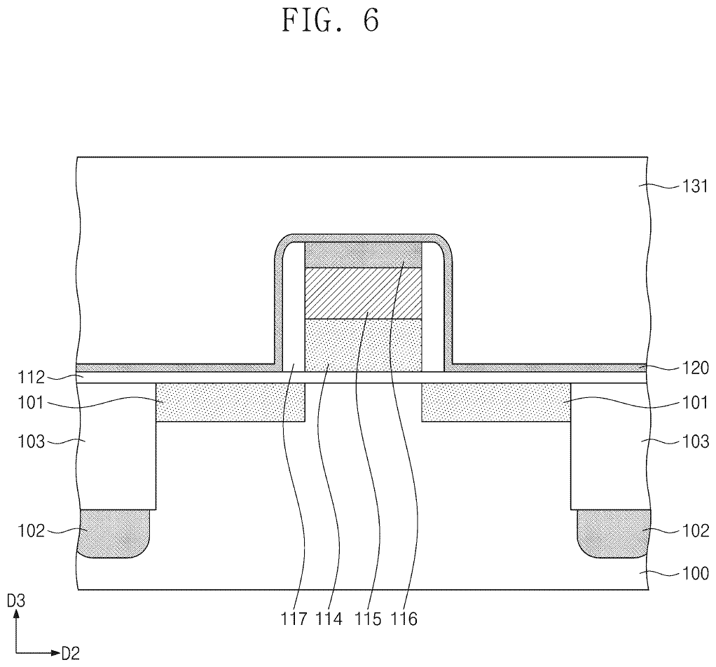

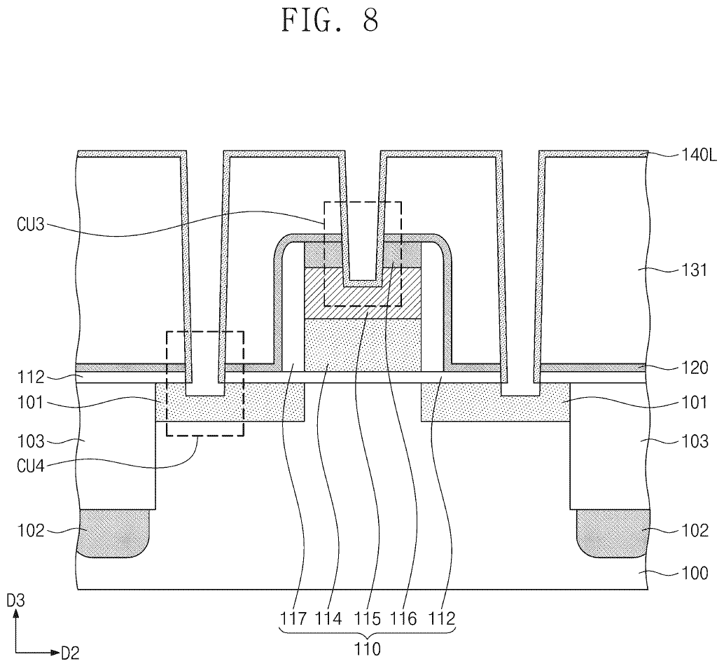

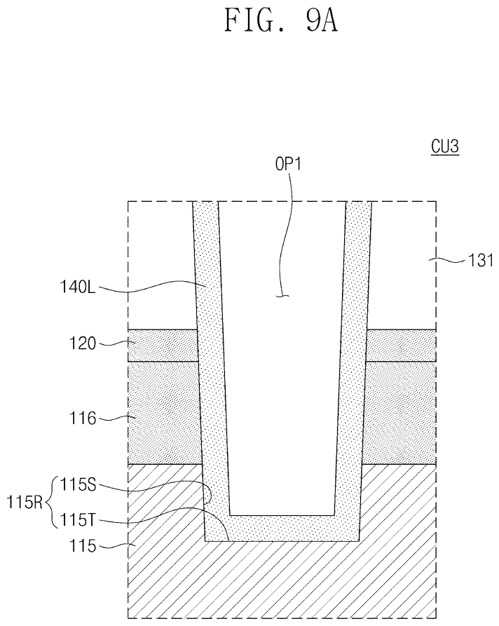

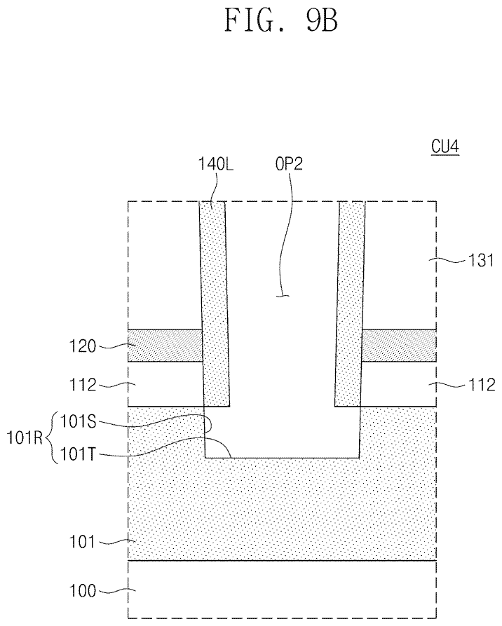

FIGS. 6, 7, 8, 10, 11, 12, 13, and 14 are sectional views illustrating a method of fabricating the example semiconductor device of FIG. 3. FIG. 9A is an enlarged sectional view illustrating a portion ‘CU3’ of FIG. 8. FIG. 9B is an enlarged sectional view illustrating a portion ‘CU4’ of FIG. 8.

Referring to FIG. 5, the isolation regions 102 and the device isolation layers 103 may be formed on the substrate 100. The gate insulating layer 112, the first gate conductive pattern 114, the second gate conductive pattern 115, and the gate capping pattern 116 may be formed on the substrate 100. The doped regions 101 may be formed by doping the substrate 100 with impurities of the second conductivity type. The gate spacers 117 may be formed on side surfaces of the gate insulating layer 112, the first gate conductive pattern 114, the second gate conductive pattern 115, and the gate capping pattern 116. The protection layer 120 may be formed on a top surface of the doped regions 101, side and top surfaces of the gate spacer 117, a top surface of the gate capping pattern 116, and a top surface of the device isolation layer 103. The first insulating layer 131 may be formed on the protection layer 120.

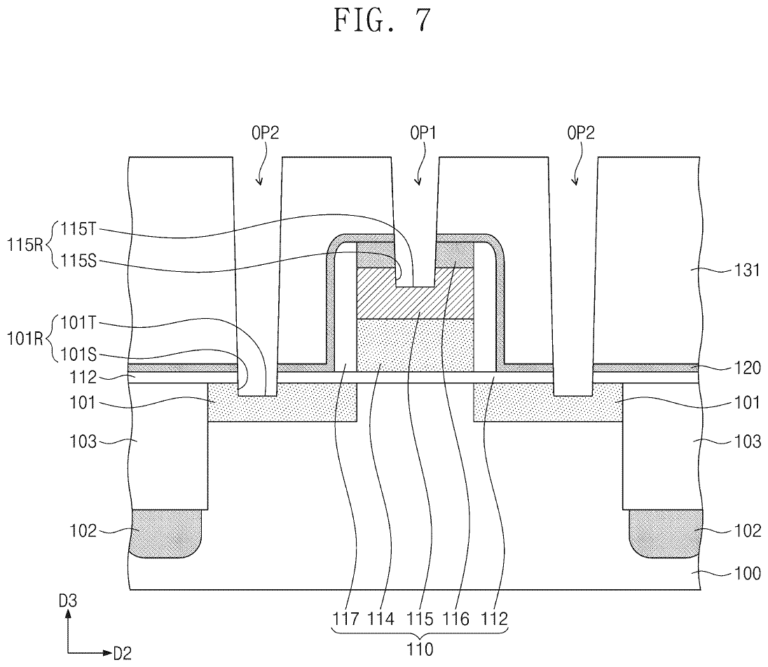

Referring to FIG. 7, a first contact hole OP1 and a second contact hole OP2 may be formed at the same time. In the present specification, the first contact hole OP1 may be referred to as a gate contact hole OP1. In the present specification, the second contact hole OP2 may be referred to as a source/drain contact hole OP2. The formation of the first and second contact holes OP1 and OP2 may include forming a mask pattern on the first insulating layer 131 and etching the first insulating layer 131 and the protection layer 120 using the mask pattern as an etch mask. The formation of the first contact hole OP1 may further include etching the gate capping pattern 116 and etching an upper portion of the second gate conductive pattern 115. As a result, the first recess 115R may be formed in the upper portion of the second gate conductive pattern 115. The first contact hole OP1 may be overlapped with the second gate conductive pattern 115 in the third direction D3 and may expose the top surface 115T of the second gate conductive pattern 115. The top surface 115T of the second gate conductive pattern 115 may correspond to the bottom surface 115T of the first recess 115R. The side surface 115S of the first recess 115R may be also exposed through the first contact hole OP1. The formation of the second contact hole OP2 may further include etching the gate insulating layer 112 and etching an upper portion of the doped region 101. As a result, the second recess 101R may be formed in the upper portion of the doped region 101. The second contact hole OP2 may be overlapped with the doped region 101 in the third direction D3 and may expose a top surface 101T of the doped region 101. The top surface 101T of the doped region 101 may correspond to the bottom surface 101T of the second recess 101R. A side surface 101S of the second recess 101R may also be exposed through the second contact hole OP2. In some implementations, an etch residue, which is left in the first and second contact holes OP1 and OP2, may be removed using a cleaning agent (e.g., HF) or a plasma.

Referring to FIGS. 8, 9A, and 9B, a film formation inhibition layer 140L may be formed to partially fill each of the first and second contact holes OP1 and OP2. The film formation inhibition layer 140L may be formed on a top surface of the first insulating layer 131, on an inner side surface of the first insulating layer 131, an inner side surface of the protection layer 120, an inner side surface of the gate capping pattern 116, and the side and bottom surfaces 115S and 115T of the first recess 115R of the second gate conductive pattern 115, which are exposed by the first contact hole OP1, and on the inner side surface of the first insulating layer 131, an inner side surface of the protection layer 120, and an inner side surface of the gate insulating layer 112, which are exposed by the second contact hole OP2. The film formation inhibition layer 140L may not fill the second recess 101R of the doped region 101. The film formation inhibition layer 140L may not be substantially formed on the side and bottom surfaces 101S and 101T of the second recess 101R. The film formation inhibition layer 140L may contain a halogen element. The formation of the film formation inhibition layer 140L may include performing a thermal treatment process in a halogen gas atmosphere. The halogen element may be adsorbed on the top surface of the first insulating layer 131, on the inner side surface of the first insulating layer 131, the inner side surface of the protection layer 120, the inner side surface of the gate capping pattern 116, the side and bottom surfaces 115S and 115T of the first recess 115R of the second gate conductive pattern 115, which are exposed by the first contact hole OP1, and on the inner side surface of the first insulating layer 131, the inner side surface of the protection layer 120, and the inner side surface of the gate insulating layer 112, which are exposed by the second contact hole OP2. For example, the first insulating layer 131 may include silicon oxide (SiO₂), and a surface of the first insulating layer 131 may contain Si—OH groups which are formed by replacing one of the oxygen atoms with a hydrogen atom. In the halogen gas atmosphere, —OH may react with the halogen element and may be replaced with, for example, —OF, —OCl, or —OBr. The halogen element may be easily absorbed on the exposed surfaces of the protection layer 120, the gate capping pattern 116, the gate insulating layer 112, and the second gate conductive pattern 115, which are formed of silicon nitride, silicon oxide, or a metallic material (e.g., tungsten). However, the halogen element may not substantially react with silicon of the doped region 101, and thus, the halogen element may not be substantially adsorbed on the exposed surface of the doped region 101. As a result, the film formation inhibition layer 140L may be formed to expose the top surface 101T and the side surface 101S of the doped region 101.

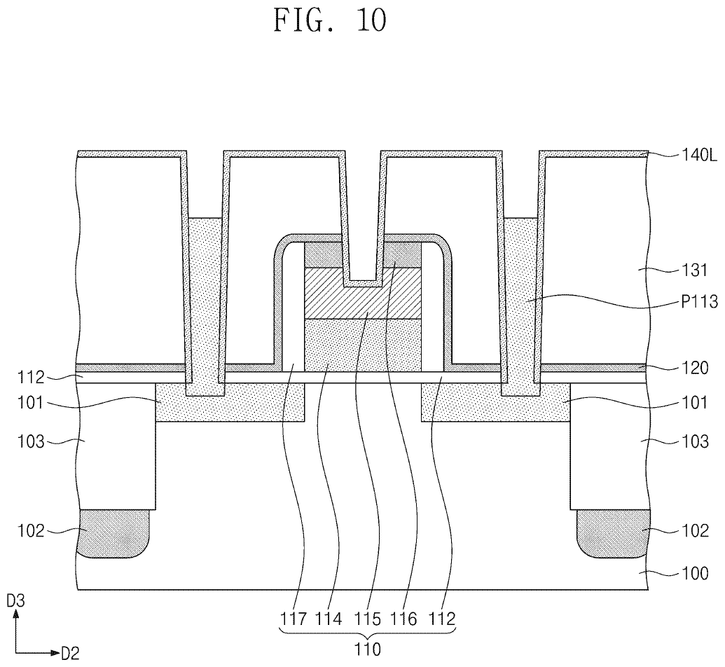

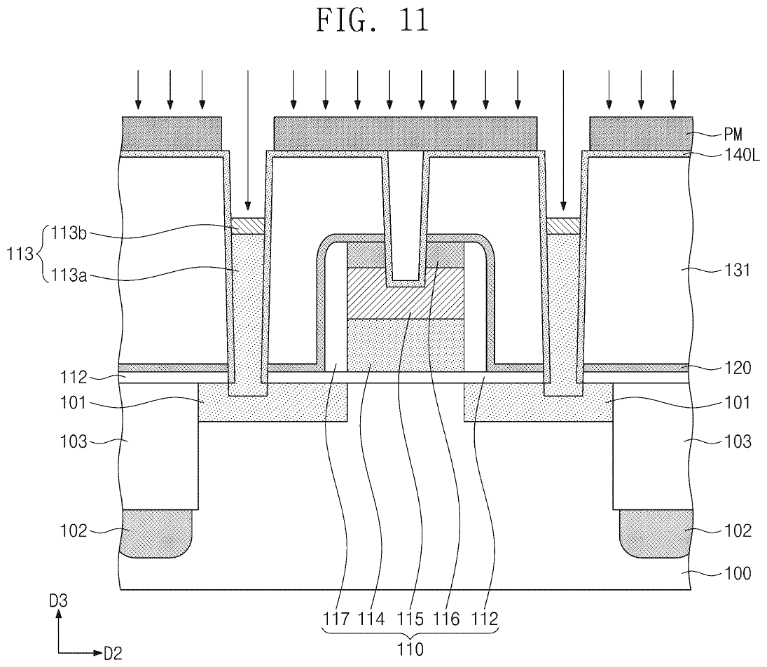

Referring to FIG. 10, a preliminary source/drain pattern P113 may be formed to fill a portion of the second contact hole OP2. The formation of the preliminary source/drain pattern P113 may include depositing a silicon precursor to selectively form the preliminary source/drain pattern P113 in the second contact hole OP2. In some implementations, the silicon precursor may include at least one of silane (SiH₄) or disilane (Si₂H₆). The deposition of the silicon precursor may include performing a chemical vapor deposition (CVD) process at a first temperature. The silicon precursor may be formed on a region where the film formation inhibition layer 140L is not formed. Thus, the preliminary source/drain pattern P113 may be selectively formed on the exposed surface of the doped region 101, even when an additional mask is not disposed on the first contact hole OP1. At this stage, the preliminary source/drain pattern P113 may include amorphous silicon. Next, a thermal treatment process may be performed at a second temperature higher than the first temperature, and thus, the crystal structure of the preliminary source/drain pattern P113 may be changed from the amorphous structure to polycrystalline structure. The thermal treatment process may include, for example, a laser annealing process.

Referring to FIG. 11, a mask pattern PM may be formed to cover the second contact hole OP2 but expose the first contact hole OP1. For example, the mask pattern PM may be formed by coating, exposing, and developing a photoresist material.

The first and second portions 113a and 113b of the source/drain pattern 113 may be formed by doping an upper portion of the preliminary source/drain pattern P113 with impurities of the second conductivity type. In some implementations, the upper portion of the preliminary source/drain pattern P113 may be doped with the impurities of the second conductivity type, and thus, the second portion 113b of the source/drain pattern 113 may be formed to have an impurity concentration that is higher than that of the first portion 113a of the source/drain pattern 113. The process of doping the impurities of the second conductivity type may include an ion implantation process using phosphorus (P) as the impurity. Thereafter, the mask pattern PM may be removed.

In a method of fabricating a semiconductor device, the first and second contact holes OP1 and OP2, which expose the gate metal pattern 115 and the doped region 101, respectively, may be formed at the same time. Next, the film formation inhibition layer 140L containing a halogen element may be formed on the first and second contact holes OP1 and OP2. The film formation inhibition layer 140L may be formed on an exposed surface of the gate metal pattern 115, not on a surface of the doped region 101. As a result, there may be no need to form the first contact hole OP1 through an additional process, which is performed after the formation of the second contact hole OP2 and the formation of the source/drain pattern 113, or to perform an additional process to remove a silicon layer from a region other than the doped region 101. Thus, it may be possible to efficiently fabricate the semiconductor device.

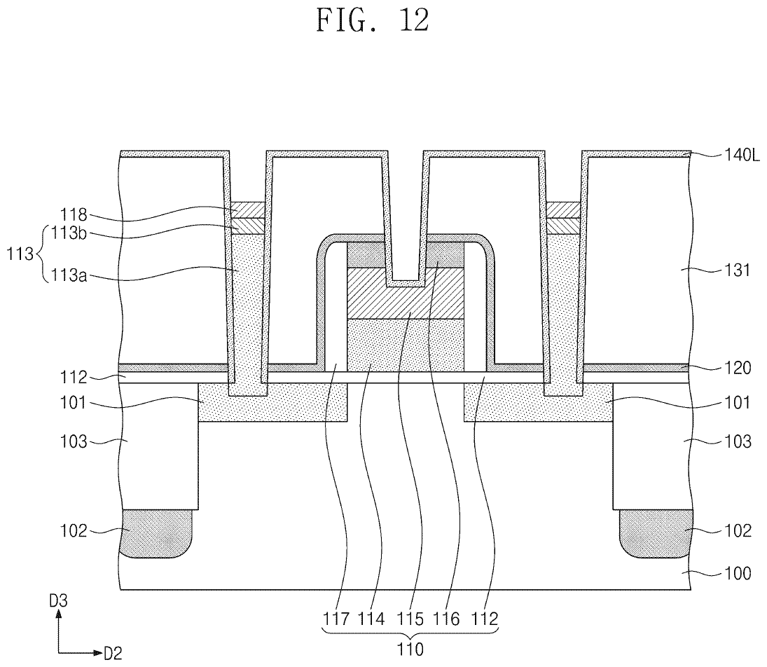

Referring to FIG. 12, the junction pattern 118 may be formed on the second portion 113b of the source/drain pattern 113. The formation of the junction pattern 118 may include selectively depositing a metal layer (e.g., Co) on the second portion 113b of the source/drain pattern 113 to form a silicide layer (e.g., CoSiₓ).

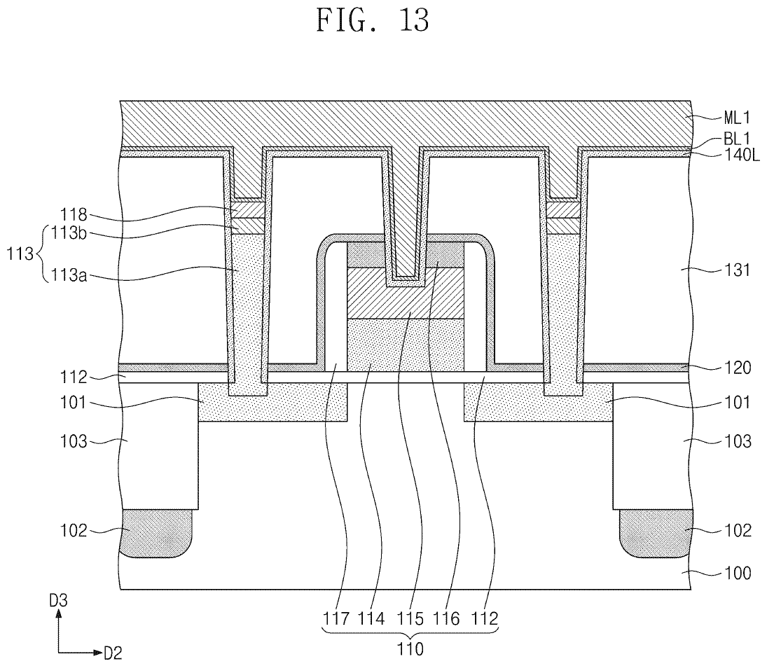

Referring to FIG. 13, a first barrier layer BL1 and a first conductive layer ML1 may be sequentially formed to fill remaining portions of the first and second contact holes OP1 and OP2. The formation of the first barrier layer BL1 may include depositing at least one of a titanium layer, a titanium nitride layer, a tantalum layer, or a tantalum nitride layer. The formation of the first conductive layer ML1 may include depositing at least one of a copper layer, an aluminum layer, a silver layer, a tungsten layer, a palladium layer, or a tungsten layer. In some implementations, the first conductive layer ML1 may be formed by a tungsten layer. The first barrier layer BL1 and the first conductive layer ML1 may be formed using, for example, an atomic layer deposition method.

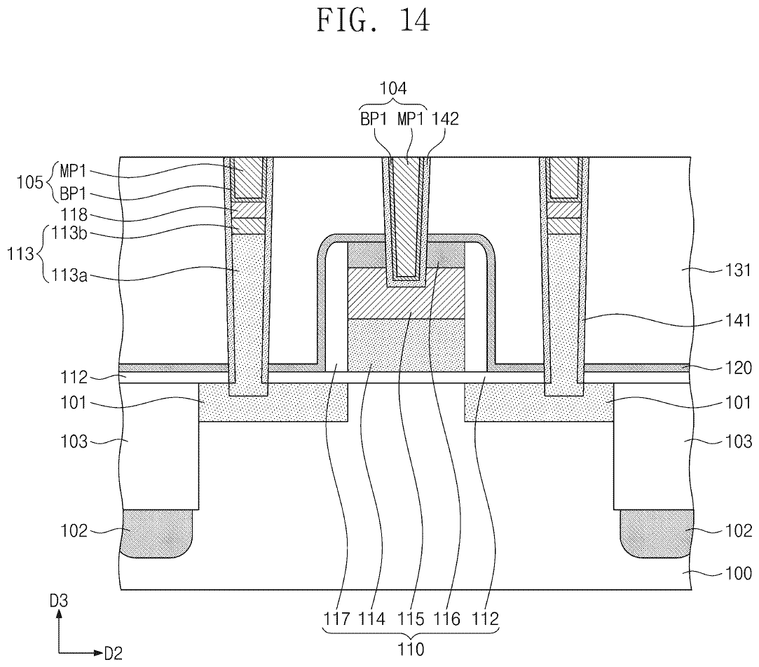

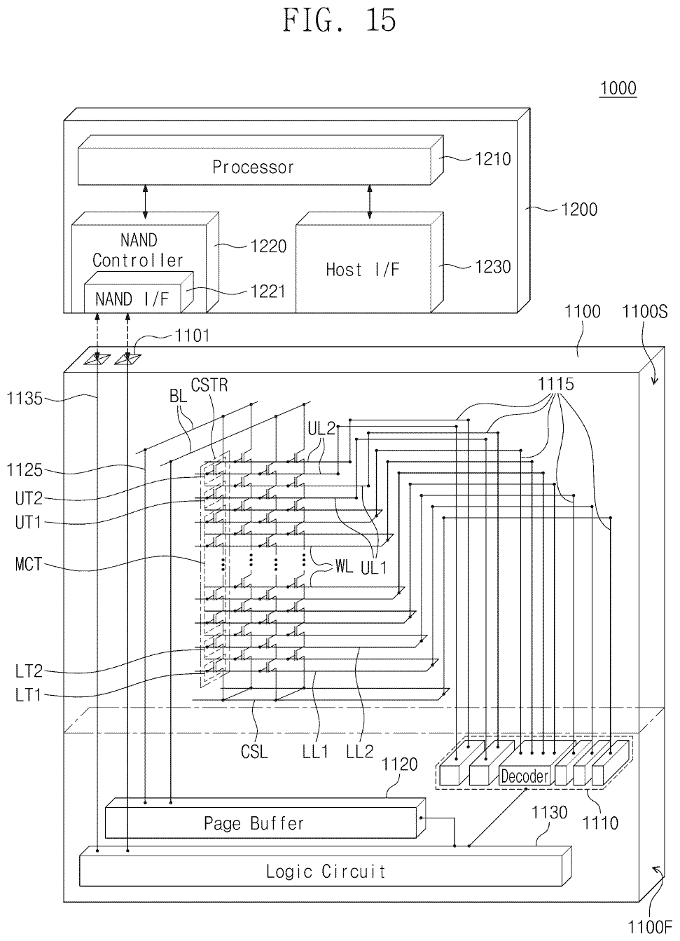

Referring to FIG. 14, a planarization process may be performed on the first barrier layer BL1, the first conductive layer ML1, and the film formation inhibition layer 140L to expose the top surface of the first insulating layer 131. As a result of the planarization process on the first barrier layer BL1 and the first conductive layer ML1, the first contact 104 including the first barrier pattern BP1 and the first conductive pattern MP1 and the second contact 105 including the second barrier pattern BP2 and the second conductive pattern MP2 may be formed. As a result of the planarization process on the film formation inhibition layer 140L, the first and second film formation inhibition patterns 142 and 141 may be formed.

Referring back to FIG. 3, the second insulating layer 152 may be formed on the first contact 104, the second contact 105, and the first insulating layer 131. The second insulating layer 152 may be etched to expose a top surface of the first contact 104 and a top surface of the second contact 105. Next, a second barrier layer and a second conductive layer may be formed and then may be patterned to form the conductive line 151, which is connected to each of the first and second contacts 104 and 105.

FIG. 15 is a schematic diagram illustrating an electronic system including an example semiconductor device.

Referring to FIG. 15, an electronic system 1000 may include a semiconductor device 1100 and a controller 1200, which is electrically connected to the semiconductor device 1100. The electronic system 1000 may be a storage device including one or more semiconductor devices 1100 or an electronic device including the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device and may be, for example, a NAND FLASH memory device. The semiconductor device 1100 may include a first structure 1100F and a second structure 1100S on the first structure 1100F. In some implementations, the first structure 1100F may be disposed beside the second structure 1100S. The first structure 1100F may be a peripheral circuit structure, which includes a decoder circuit 1110, a page buffer 1120, and a logic circuit 1130. The second structure 1100S may be a memory cell structure, which includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2, which are adjacent to the common source line CSL, upper transistors UT1 and UT2, which are adjacent to the bit line BL, and a plurality of memory cell transistors MCT, which are disposed between the lower transistors LT1 and LT2 and the upper transistors UT1 and UT2. The number of the lower transistors LT1 and LT2 and the number of the upper transistors UT1 and UT2 may be variously changed, according to implementations.

In some implementations, the upper transistors UT1 and UT2 may include a string selection transistor, and the lower transistors LT1 and LT2 may include a ground selection transistor. The gate lower lines LL1 and LL2 may be respectively used as gate electrodes of the lower transistors LT1 and LT2. The word lines WL may be used as gate electrodes of the memory cell transistors MCT, respectively, and the gate upper lines UL1 and UL2 may be used as gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F into the second structure 1100S. The bit lines BL may be electrically connected to the page buffer 1120 through second connection lines 1125, which are extended from the first structure 1100F into the second structure 1100S.

In the first structure 1100F, the decoder circuit 1110 and the page buffer 1120 may be configured to perform a control operation on at least selected one of the memory cell transistors MCT. The decoder circuit 1110 and the page buffer 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 through an input/output connection line 1135, which is extended from the first structure 1100F to the second structure 1100S.

The controller 1200 may include a processor 1210, a NAND controller 1220, and a host interface 1230. In some implementations, the electronic system 1000 may include a plurality of semiconductor devices 1100, and in this case, the controller 1200 may be configured to control the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221 which is used for communication with the semiconductor device 1100. The NAND interface 1221 may be used to transmit and receive control commands to control the semiconductor device 1100, data to be written in or read from the memory cell transistors MCT of the semiconductor device 1100, and so forth. The host interface 1230 may be configured to allow for communication between the electronic system 1000 and an external host. When a control command is received from the external host through the host interface 1230, the processor 1210 may control the semiconductor device 1100 in response to the control command.

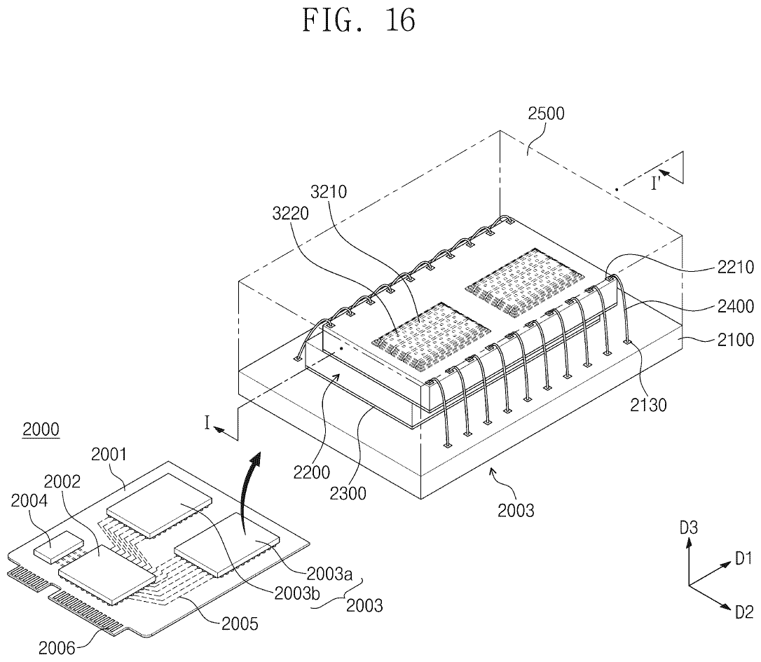

FIG. 16 is a perspective view schematically illustrating an electronic system including an example semiconductor device.

Referring to FIG. 16, an electronic system 2000 may include a main substrate 2001 and a controller 2002, one or more semiconductor packages 2003, and a DRAM 2004, which are mounted on the main substrate 2001. The semiconductor package 2003 and the DRAM 2004 may be connected to the controller 2002 and to each other by interconnection patterns 2005, which are formed in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. In some implementations, the electronic system 2000 may communicate with the external host, in accordance with one of interfaces, such as universal serial bus (USB), peripheral component interconnect express (PCI-Express), serial advanced technology attachment (SATA), universal flash storage (UFS) M-PHY, or the like. In some implementations, the electronic system 2000 may be driven by an electric power, which is supplied from the external host through the connector 2006. The electronic system 2000 may further include a power management integrated circuit (PMIC) that is configured to distribute a power, which is supplied from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory that is configured to relieve technical difficulties caused by a difference in speed between the semiconductor package 2003, which serves as a data storage device, and an external host. In some implementations, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200, which are provided on the package substrate 2100, adhesive layers 2300, which are respectively disposed on bottom surfaces of the semiconductor chips 2200, a connection structure 2400, which electrically connects the semiconductor chips 2200 to the package substrate 2100, and a molding layer 2500, which is provided on the package substrate 2100 to cover the semiconductor chips 2200 and the connection structure 2400.

The package substrate 2100 may be a printed circuit board, which includes package upper pads 2130. Each of the semiconductor chips 2200 may include an input/output pad 2210. The input/output pad 2210 may correspond to the input/output pad 1101 of FIG. 15. Each of the semiconductor chips 2200 may include gate stacks 3210 and memory channel structures 3220. Each of the semiconductor chips 2200 may include a semiconductor device.

In some implementations, the connection structure 2400 may be a bonding wire electrically connecting the input/output pad 2210 to the package upper pads 2130. Thus, in each of the first and second semiconductor packages 2003a and 2003b, the semiconductor chips 2200 may be electrically connected to each other in a bonding wire manner and may be electrically connected to the package upper pads 2130 of the package substrate 2100. Alternatively, in each of the first and second semiconductor packages 2003a and 2003b, the semiconductor chips 2200 may be electrically connected to each other by a connection structure including through-silicon vias (TSVs) (not shown in the figure), rather than by the connection structure 2400 provided in the form of bonding wires.

In some implementations, the controller 2002 and the semiconductor chips 2200 may be included in a single package. In some implementations, the controller 2002 and the semiconductor chips 2200 may be mounted on an additional interposer substrate different from the main substrate 2001 and may be connected to each other through interconnection lines, which are provided in the interposer substrate.

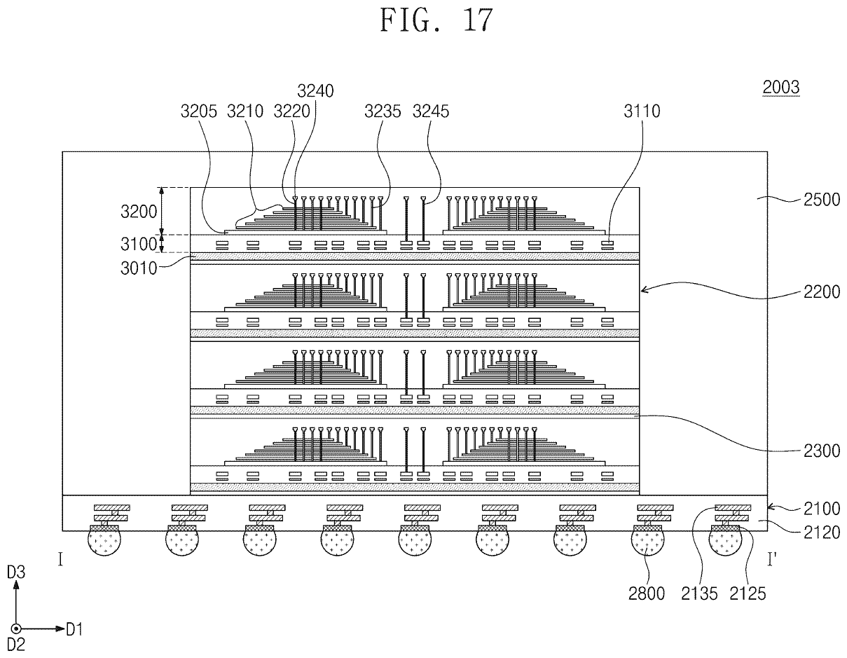

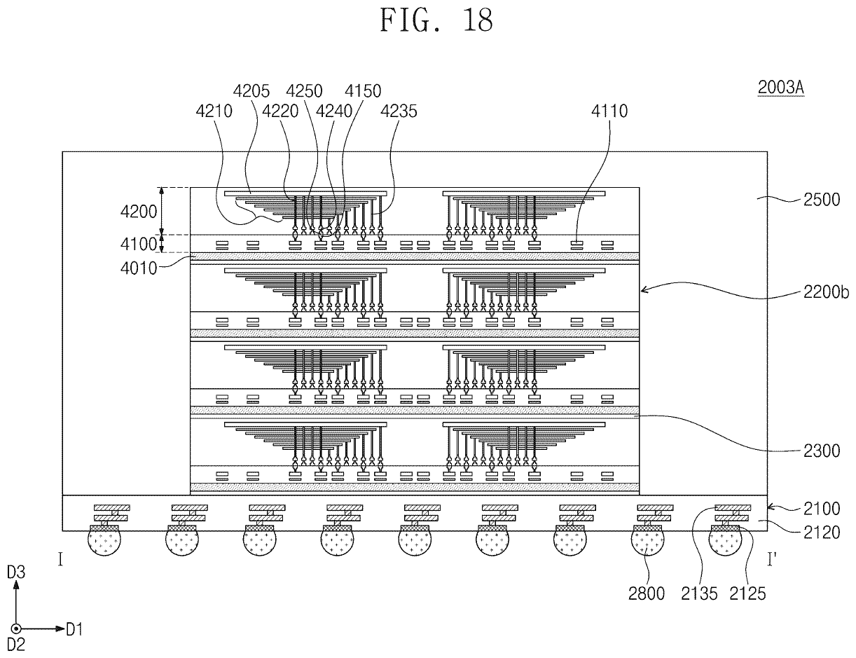

FIGS. 17 and 18 are sectional views, each of which schematically illustrates an example semiconductor package. Each of FIGS. 17 and 18 schematically illustrates an example of the semiconductor package 2003 of FIG. 16 taken along a line I-I′ of FIG. 16.

Referring to FIG. 17, in the semiconductor package 2003, the package substrate 2100 may be a printed circuit board. The package substrate 2100 may include a package substrate body portion 2120, package upper pads 2130 (e.g., of FIG. 16) disposed on a top surface of the package substrate body portion 2120, lower pads 2125 disposed on or exposed through a bottom surface of the package substrate body portion 2120, and internal lines 2135 provided in the package substrate body portion 2120 to electrically connect the upper pads 2130 to the lower pads 2125. The upper pads 2130 may be electrically connected to the connection structures 2400 (e.g., of FIG. 16). The lower pads 2125 may be connected to the interconnection patterns 2005 of the main substrate 2001 of the electronic system 2000, which is shown in FIG. 16, through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region provided with peripheral lines 3110. The second structure 3200 may include a common source line 3205, a gate stack 3210 on the common source line 3205, the memory channel structures 3220, which are provided to extend through the gate stack 3210, bit lines 3240, which are electrically connected to the memory channel structures 3220, and gate contact plugs 3235, which are electrically connected to the word lines WL (e.g., see FIG. 15) of the gate stack 3210.

Each of the semiconductor chips 2200 may be electrically connected to the peripheral lines 3110 of the first structure 3100 and may include a penetration line 3245, which is extended into the second structure 3200. The penetration line 3245 may be disposed outside the gate stack 3210. In some implementations, the penetration line 3245 may be provided to extend through the gate stack 3210. Each of the semiconductor chips 2200 may further include the input/output pad 2210 of FIG. 16.

Referring to FIG. 18, in a semiconductor package 2003A, each of semiconductor chips 2200b may include a semiconductor substrate 4010, a first structure 4100 on the semiconductor substrate 4010, and a second structure 4200, which is disposed on the first structure 4100 and is bonded to the first structure 4100 by a wafer bonding method.

The first structure 4100 may include a peripheral circuit region, in which a peripheral line 4110 and first junction structures 4150 are provided. The second structure 4200 may include a common source line 4205, a gate stack 4210 between the common source line 4205 and the first structure 4100, memory channel structures 4220, which are provided to extend through the gate stack 4210, bit lines 4240 electrically connected to the memory channel structures 4220, gate contact plugs 4235, which are electrically connected to the word lines WL of FIG. 15 of the gate stack 4210, respectively, and second junction structures 4250. For example, the second junction structures 4250 may be electrically connected to the memory channel structures 4220, respectively, through the bit lines 4240, which are electrically connected to the memory channel structures 4220. The first junction structures 4150 of the first structure 4100 and the second junction structures 4250 of the second structure 4200 may be bonded to each other. In some implementations, the bonding portion of the first and second junction structures 4150 and 4250 may be formed of copper (Cu). Each of the semiconductor chips 2200b may further include the input/output pad 2210 of FIG. 16.

The semiconductor chips 2200 of FIG. 17 and the semiconductor chips 2200b of FIG. 18 may be electrically connected to each other by the connection structures 2400 of FIG. 16, which may be provided in the form of bonding wires. However, in some implementations, semiconductor chips, which are provided in the same semiconductor package as the semiconductor chips 2200 of FIG. 17 or the semiconductor chips 2200b of FIG. 18, may be electrically connected to each other through a connection structure including through-silicon vias (TSVs).

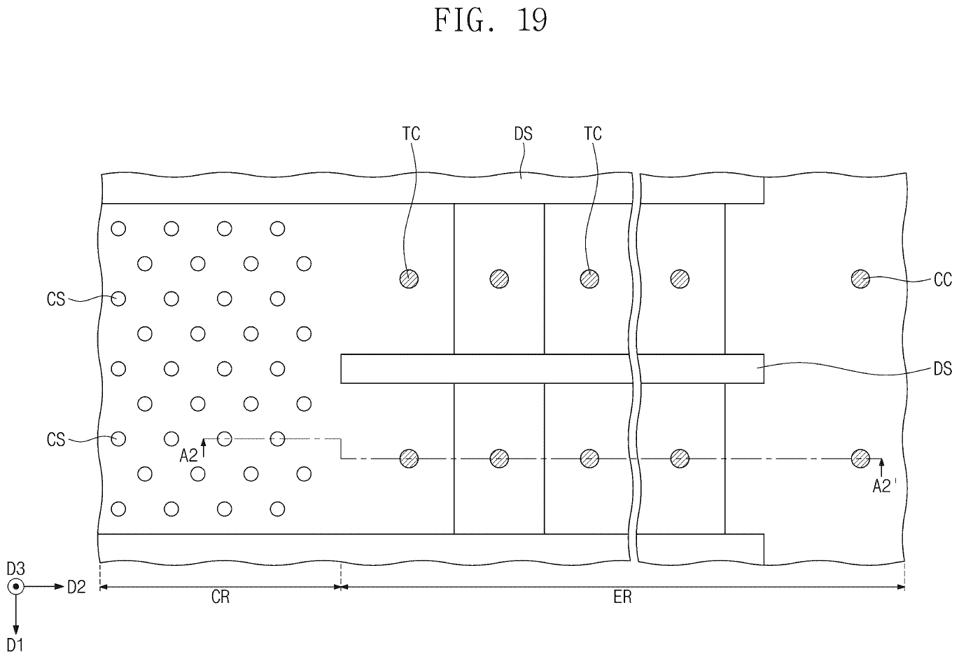

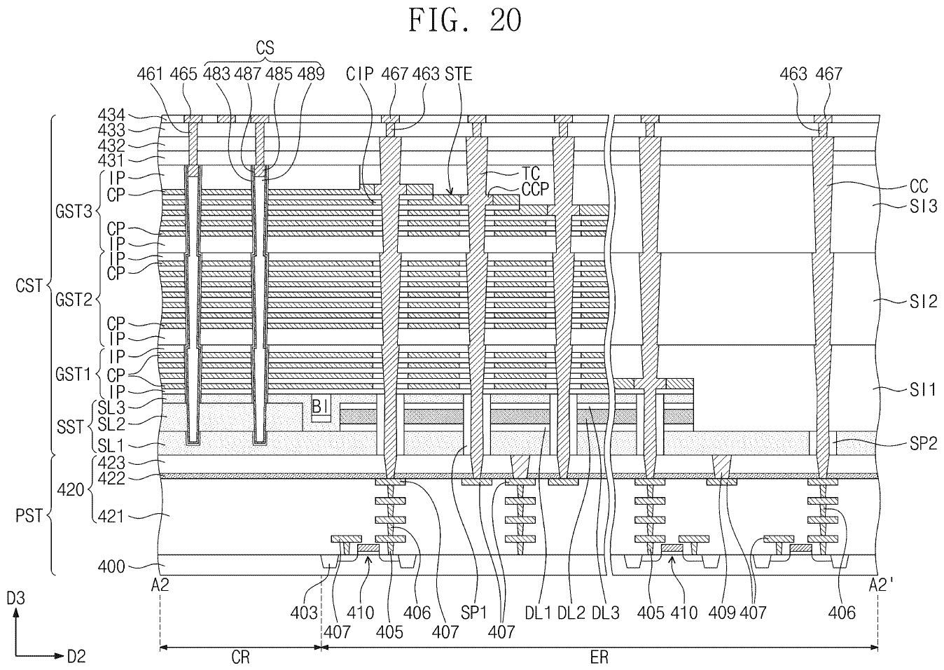

FIG. 19 is a plan view of an example semiconductor device. FIG. 20 is a sectional view taken along a line A2-A2′ of FIG. 19.

Referring to FIGS. 19 and 20, a semiconductor device may include a peripheral circuit structure PST and a memory cell structure CST on the peripheral circuit structure PST.

The peripheral circuit structure PST may include a substrate 400. The peripheral circuit structure PST may include an insulating structure 420 on the substrate 400. The insulating structure 420 may include a first insulating layer 421, a second insulating layer 422 on the first insulating layer 421, and a third insulating layer 423 on the second insulating layer 422. The first to third insulating layers 421, 422, and 423 may include at least one of insulating materials. As an example, the first and third insulating layers 421 and 423 may be formed of or include at least one of oxide materials, and the second insulating layer 422 may be formed of or include at least one of nitride materials.

In some implementations, each of the first to third insulating layers 421, 422, and 423 may be a multiple insulating layer.

Device isolation layers 403 may be provided in the substrate 400. The peripheral circuit structure PST may further include a transistor 410. The transistor 410 may be provided between the substrate 400 and the insulating structure 420. In some implementations, the transistor 410 may include a gate structure, a doped region, a source/drain pattern, a junction pattern, a first contact, a first film formation inhibition pattern, a second contact, and a second film formation inhibition pattern, similar to the transistor of FIG. 3.

The peripheral circuit structure PST may further include first peripheral circuit contacts (not shown), second peripheral circuit contacts 405, third peripheral circuit contacts 406, and peripheral conductive lines 407.

The first peripheral circuit contact may be connected to a gate structure of the transistor 410. The first peripheral circuit contact may correspond to the first contact 104 of FIG. 3. The first film formation inhibition pattern 142 of FIG. 3 may be interposed between the first peripheral circuit contact and the gate structure of the transistor 410.

The second peripheral circuit contact 405 may be connected to a doped region of the transistor 410. The second peripheral circuit contact 405 may correspond to the group of the source/drain pattern 113, the junction pattern 118, and the second contact 105 of FIG. 3. The second film formation inhibition pattern 141 of FIG. 3 may be interposed between the second peripheral circuit contact 405 and the first insulating layer 421. The second film formation inhibition pattern 141 of FIG. 3 may not be interposed between the second peripheral circuit contact 405 and the doped region of the transistor 410.

The peripheral conductive line 407 may be connected to the second peripheral circuit contact 405 or the third peripheral circuit contact 406. The third peripheral circuit contact 406 may be disposed between the peripheral conductive lines 407. The second peripheral circuit contact 405, the third peripheral circuit contact 406, and the peripheral conductive line 407 may be provided in the first insulating layer 421 of the insulating structure 420. The third peripheral circuit contact 406 and the peripheral conductive line 407 may include a conductive material. In some implementations, the second peripheral circuit contact 405 and the peripheral conductive line 407 may include at least one of metallic materials.

The peripheral circuit structure PST may further include a source connection contact 409. The source connection contact 409 may be connected to the peripheral conductive line 407 and a first source layer SL1, which will be described below. The source connection contact 409 may be provided to extend through the second and third insulating layers 422 and 423 of the peripheral circuit insulating structure 420. The source connection contact 409 may include at least one of conductive materials. As an example, the source connection contact 409 may be formed of or include poly silicon.

The memory cell structure CST may include a source structure SST, a first gate stack GST1, a second gate stack GST2, a third gate stack GST3, memory channel structures CS, a first stepwise insulating layer SI1, a second stepwise insulating layer SI2, a third stepwise insulating layer SI3, a first cover insulating layer 431, a second cover insulating layer 432, a third cover insulating layer 433, a fourth cover insulating layer 434, division structures DS (FIG. 19), third contacts 461, fourth contacts 463, bit lines 465, conductive lines 467, penetration contacts TC, and connection contacts CC.

The source structure SST may include a cell region CR and an extension region ER. The cell region CR and the extension region ER may be two separate regions, when viewed in the plan view defined by the first and second directions D1 and D2.

The source structure SST may include a first source layer SL1 provided on the peripheral circuit structure PST, a second source layer SL2 provided on the first source layer SL1, a first dummy layer DL1, a second dummy layer DL2, and a third dummy layer DL3 provided on the first source layer SL1, and a third source layer SL3 provided on the second source layer SL2 and the first to third dummy layers DL1, DL2, and DL3.

The first to third source layers SL1, SL2, and SL3 may include at least one of conductive materials. As an example, the first to third source layers SL1, SL2, and SL3 may be formed of or include poly silicon. The second source layer SL2 may be disposed in the cell region CR. The second source layer SL2 may be a common source line.

The first dummy layer DL1, the second dummy layer DL2, the third dummy layer DL3 may be sequentially provided on the first source layer SL1 in the third direction D3. The first to third dummy layers DL1, DL2, and DL3 may be disposed in the extension region ER. The first to third dummy layers DL1, DL2, and DL3 may be disposed at the same level as the second source layer SL2. The first to third dummy layers DL1, DL2, and DL3 may include at least one of insulating materials. In some implementations, the first and third dummy layers DL1 and DL3 may be formed of or include the same insulating material, and the second dummy layer DL2 may be formed of or include an insulating material different from the first and third dummy layers DL1 and DL3. As an example, the second dummy layer DL2 may be formed of or include at least one of nitride materials, and the first and third dummy layers DL1 and DL3 may be formed of or include at least one of oxide materials.

The third source layer SL3 may cover the second source layer SL2 and the first to third dummy layers DL1, DL2, and DL3. The third source layer SL3 may be extended from the cell region CR to the extension region ER.

In some implementations, the source structure SST may further include an insulating gapfill layer BI on the third source layer SL3. The insulating gapfill layer BI may be provided between the cell region CR and the extension region ER. The insulating gapfill layer BI may be provided between the second source layer SL2 and the first to third dummy layers DL1, DL2, and DL3. The second source layer SL2 and the first to third dummy layers DL1, DL2, and DL3 may be spaced apart from each other in the second direction D2, and the insulating gapfill layer BI and a portion of the third source layer SL3 enclosing the insulating gapfill layer BI may be provided between the second source layer SL2 and the first to third dummy layers DL1, DL2, and DL3. The insulating gapfill layer BI may include at least one of insulating materials.

The source structure SST may further include first source insulating patterns SP1 and second source insulating patterns SP2. The first and second source insulating patterns SP1 and SP2 may be disposed in the extension region ER. The first source insulating pattern SP1 may enclose the penetration contact TC. The second source insulating pattern SP2 may enclose the connection contact CC.

The first source insulating pattern SP1 may be provided to extend through the third source layer SL3, the first to third dummy layers DL1, DL2, and DL3, and the first source layer SL1. The first source insulating pattern SP1 may be enclosed by the third source layer SL3, the first to third dummy layers DL1, DL2, and DL3, and the first source layer SL1. The second source insulating pattern SP2 may be provided to extend through the first source layer SL1. The second source insulating pattern SP2 may be enclosed by the first source layer SL1. The first and second source insulating patterns SP1 and SP2 may include at least one of insulating materials. As an example, the first and second source insulating patterns SP1 and SP2 may be formed of or include at least one of oxide materials.

The first gate stack GST1 may be provided on the source structure SST. The second gate stack GST2 may be provided on the first gate stack GST1. The third gate stack GST3 may be provided on the second gate stack GST2. The number of the gate stacks GST1, GST2, and GST3 may not be limited to the illustrated example. In some implementations, the number of the gate stacks GST1, GST2, and GST3 may be equal to or less than 2 or may be equal to or greater than 4.

Each of the first to third gate stacks GST1, GST2, and GST3 may include insulating patterns IP and conductive patterns CP, which are alternately stacked on top of each other in the third direction D3. A staircase structure STE may be defined by the insulating patterns IP and the conductive patterns CP.

The insulating patterns IP may include at least one of insulating materials. As an example, the insulating patterns IP may be formed of or include at least one of oxide materials. The conductive patterns CP may include at least one of conductive materials. As an example, the conductive patterns CP may be formed of or include tungsten.

Each of the first to third gate stacks GST1, GST2, and GST3 may further include contact insulating patterns CIP. The contact insulating pattern CIP may be disposed at the same level as the conductive pattern CP. The contact insulating pattern CIP may enclose the penetration contact TC. The contact insulating pattern CIP may be disposed between the penetration contact TC and the conductive pattern CP. The contact insulating pattern CIP may include at least one of insulating materials. As an example, the contact insulating pattern CIP may be formed of or include at least one of oxide materials.

The first stepwise insulating layer SI1 may be provided on the source structure SST. The first stepwise insulating layer SI1 may be disposed at the same level as the first gate stack GST1. The second stepwise insulating layer SI2 may be provided on the first stepwise insulating layer SI1. The second stepwise insulating layer SI2 may be disposed at the same level as the second gate stack GST2. The third stepwise insulating layer SI3 may be provided on the second stepwise insulating layer SI2. The third stepwise insulating layer SI3 may be disposed at the same level as the third gate stack GST3. The first to third stepwise insulating layers SI1, SI2, and SI3 may include at least one of insulating materials. As an example, the first to third stepwise insulating layers SI1, SI2, and SI3 may be formed of or include at least one of oxide materials.

The memory channel structures CS may be extended in the third direction D3 to extend through the first gate stack GST1, the second gate stack GST2, the third gate stack GST3, the third source layer SL3, and the second source layer SL2. Each of the memory channel structures CS may include an insulating capping layer 489, a channel layer 487 enclosing the insulating capping layer 489, and a memory layer 483 enclosing the channel layer 487.

The insulating capping layer 489 may include at least one of insulating materials. As an example, the insulating capping layer 489 may be formed of or include at least one of oxide materials. The channel layer 487 may include at least one of conductive materials. As an example, the channel layer 487 may be formed of or include poly silicon. The channel layer 487 may be electrically connected to the second source layer SL2. The second source layer SL2 may extend through the memory layer 483 and may be connected to the channel layer 487.

The memory layer 483 may be configured to store data. In some implementations, the memory layer 483 may include a tunnel insulating layer enclosing the channel layer 487, a data storing layer enclosing the tunnel insulating layer, and a blocking layer enclosing the data storing layer.

Each of the memory channel structures CS may further include a bit line pad 485 provided on the channel layer 487. The bit line pad 485 may include at least one of conductive materials. As an example, the bit line pad 485 may be formed of or include at least one of poly silicon or metallic materials.

The first cover insulating layer 431 may be provided on the third gate stack GST3, the third stepwise insulating layer SI3, and the memory channel structures CS. The first cover insulating layer 431 may include at least one of insulating materials.

The second cover insulating layer 432 may be provided on the first cover insulating layer 431. The second cover insulating layer 432 may include at least one of insulating materials.

The penetration contacts TC may be extended in the third direction D3. The penetration contact TC may be provided to extend through the second cover insulating layer 432, the first cover insulating layer 431, at least one of the first stepwise insulating layer SI1 and the first gate stack GST1, at least one of the second stepwise insulating layer SI2 and the second gate stack GST2, at least one of the third stepwise insulating layer SI3 and the third gate stack GST3, the third source layer SL3, the third dummy layer DL3, the second dummy layer DL2, the first dummy layer DL1, the first source layer SL1, the first source insulating pattern SP1, the third insulating layer 423, and the second insulating layer 422. The penetration contact TC may be connected to the peripheral conductive line 407. The penetration contact TC may include a contact connecting portion CCP connected to the conductive pattern CP. The penetration contact TC may include at least one of conductive materials.

The connection contacts CC may be extended in the third direction D3. The connection contact CC may be provided to extend through the second cover insulating layer 432, the first cover insulating layer 431, the first stepwise insulating layer SI1, the second stepwise insulating layer SI2, the third stepwise insulating layer SI3, the first source layer SL1, the second source insulating pattern SP2, the third insulating layer 423, and the second insulating layer 422. The connection contact CC may be connected to the peripheral conductive line 407.

The third cover insulating layer 433 may be provided on the second cover insulating layer 432, the penetration contacts TC, and the connection contacts CC. The fourth cover insulating layer 434 may be provided on the third cover insulating layer 433. The third and fourth cover insulating layers 433 and 434 may include at least one of insulating materials.

The division structures DS may be provided to extend through the first to third gate stacks GST1, GST2, and GST3. The division structures DS may be extended in the second direction D2. The division structure DS may include at least one of insulating materials. In some implementations, the division structures DS may include at least one of conductive materials.

The third contact 461 may be connected to the memory channel structure CS. The third contact 461 may be provided to extend through the first to third cover insulating layers 431, 432, and 433. The fourth contact 463 may be connected to the penetration contact TC or the connection contact CC. The fourth contact 463 may be provided to extend through the third cover insulating layer 433. The bit line 465 may be connected to the third contact 461. The bit line 465 may be disposed in the fourth cover insulating layer 434. The bit line 465 may be extended in the first direction D1. The conductive line 467 may be connected to the fourth contact 463. The conductive line 467 may be disposed in the fourth cover insulating layer 434. The third contact 461, the fourth contact 463, the bit line 465, and the conductive line 467 may include at least one of conductive materials.

A semiconductor device may include a source/drain pattern, which is extended in a direction perpendicular to a top surface of a substrate, and a current path between the source/drain contact and a gate metal pattern may be relatively long. Accordingly, a size of a doped region may be relatively small, and an integration density of the semiconductor device may be increased.

In a method of fabricating a semiconductor device a source/drain contact hole exposing a doped region and a gate contact hole exposing a gate metal pattern may be formed at the same time. Thereafter, a film formation inhibition layer may be formed on the source/drain contact hole and the gate contact hole. The film formation inhibition layer may be formed on the gate metal pattern, not on the doped region. Thus, a source/drain pattern may be formed on the doped region to fill the source/drain contact hole, without an additional process, and this may make it possible to efficiently fabricate the semiconductor device.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been particularly shown and described, it will be understood by one of ordinary skill in the art that variations in form and detail may be made therein without departing from the spirit and scope of the attached claims.

What is claimed is:

1. A semiconductor device, comprising:
a substrate;
a doped region on the substrate;
a gate structure on the substrate;
an insulating layer covering the gate structure and the doped region;
a first contact extending through the insulating layer and connected to the gate structure; and
a first film formation inhibition pattern disposed between the gate structure and the first contact,
wherein the first film formation inhibition pattern includes a halogen element.

2. The semiconductor device of claim 1, wherein the gate structure comprises:
a gate insulating pattern;
a gate metal pattern on the gate insulating pattern; and
a gate capping pattern on the gate metal pattern,
wherein the first contact is provided to extend through the insulating layer and the gate capping pattern and is extended to a level that is lower than a bottom surface of the gate capping pattern.

3. The semiconductor device of claim 2, wherein the gate metal pattern comprises a recess defined at an upper portion of the gate metal pattern,
wherein the first contact is provided at the recess,
wherein the first film formation inhibition pattern is interposed between side and bottom surfaces of the recess and the first contact.

4. The semiconductor device of claim 2, wherein the gate capping pattern comprises silicon nitride, and
an interface between the gate capping pattern and the first film formation inhibition pattern includes a halogen element.

5. The semiconductor device of claim 2, wherein each of the first contact and the gate metal pattern comprises tungsten.

6. The semiconductor device of claim 1, further comprising:
a source/drain pattern extending through the insulating layer and connected to the doped region; and
a second film formation inhibition pattern disposed between the insulating layer and the source/drain pattern,
wherein the second film formation inhibition pattern includes a halogen element.

7. The semiconductor device of claim 6, wherein the source/drain pattern comprises a first portion and a second portion on the first portion,
the second portion is spaced apart from the doped region,
the first and second portions comprise poly silicon,
the doped region includes impurities of a first conductivity type at a first concentration,
the second portion includes impurities of the first conductivity type at a second concentration, and
the first concentration is lower than the second concentration.

8. The semiconductor device of claim 6, wherein the doped region comprises a recess defined at an upper portion of the doped region,
the source/drain pattern is provided at the recess, and
the second film formation inhibition pattern is spaced apart from a bottom surface of the recess.

9. The semiconductor device of claim 6, further comprising a second contact on the source/drain pattern,
wherein the second contact is provided to extend through the insulating layer, and
the second contact comprises a metallic material.

10. The semiconductor device of claim 9, wherein the second film formation inhibition pattern is extended into a space between the insulating layer and the second contact.

11. The semiconductor device of claim 1, wherein the first film formation inhibition pattern is extended into a space between the insulating layer and the first contact.

12. A semiconductor device, comprising:
a substrate;
a doped region on the substrate;
a gate structure on the substrate, the gate structure comprising a gate metal pattern;
an insulating layer covering the gate structure and the doped region;
a first contact extending through the insulating layer and connected to the gate metal pattern; and
a first film formation inhibition pattern disposed between the gate metal pattern and the first contact,
wherein the first film formation inhibition pattern is in contact with a top surface of the gate metal pattern.

13. The semiconductor device of claim 12, wherein the first film formation inhibition pattern is interposed between the first contact and the insulating layer.

14. The semiconductor device of claim 12, further comprising:
a source/drain pattern extending through the insulating layer and connected to the doped region; and
a second film formation inhibition pattern disposed between the insulating layer and the source/drain pattern,
wherein the second film formation inhibition pattern is spaced apart from the doped region.

15. The semiconductor device of claim 14, wherein the first and second film formation inhibition patterns comprise the same material.

16. The semiconductor device of claim 14, further comprising:
a second contact extending through the insulating layer and disposed on the source/drain pattern; and
a junction pattern between the second contact and the source/drain pattern,
wherein the second contact comprises a metallic material,
the junction pattern comprises silicide, and
a level of a top surface of the source/drain pattern is higher than a level of the top surface of the gate metal pattern.

17. The semiconductor device of claim 14, wherein the source/drain pattern comprises a first portion and a second portion on the first portion,
the second portion is spaced apart from the doped region,
the first and second portions of the source/drain pattern comprise poly silicon,
the doped region includes impurities of a first conductivity type at a first concentration,
the second portion includes impurities of the first conductivity type at a second concentration, and
the first concentration is lower than the second concentration.

18. A semiconductor device, comprising:
a substrate;
an isolation region on the substrate;
a device isolation layer on the isolation region;
a doped region on the substrate;
a gate structure on the substrate, the gate structure comprising a gate metal pattern;
an insulating layer covering the doped region and the gate structure;
a gate contact extending through the insulating layer and connected to the gate metal pattern;
a source/drain pattern extending through the insulating layer and connected to the doped region;
a source/drain contact extending through the insulating layer, connected to the source/drain pattern, and disposed on the source/drain pattern;
a first film formation inhibition pattern disposed between the insulating layer and the gate contact; and
a second film formation inhibition pattern disposed between the insulating layer and the source/drain pattern,
wherein a level of a top surface of the source/drain pattern is higher than a level of a top surface of the gate metal pattern, and
the first and second film formation inhibition patterns include a halogen element.

19. The semiconductor device of claim 18, wherein the first film formation inhibition pattern is in contact with bottom and side surfaces of the gate contact, and
the second film formation inhibition pattern is in contact with a side surface of the source/drain pattern and is provided to expose a bottom surface of the source/drain pattern.

20. The semiconductor device of claim 18, wherein the insulating layer comprises a plurality of layers which are sequentially stacked,
the insulating layer comprises a protection layer in contact with the gate structure,
the protection layer comprises silicon nitride,
the protection layer is in contact with the first film formation inhibition pattern, and
an interface between the protection layer and the first film formation inhibition pattern includes a halogen element.
